(19) United States
(12) Patent Application Publication
(10) Pub. No.: US 2012/0252225 A1
(43) Pub. Date: Oct. 4, 2012

(54) SEMICONDUCTOR FABRICATION METHOD

(76) Inventors: Chunlong Li, Beijing (CN); Junfeng Li, Beijing (CN)

(21) Appl. No.: 13/140,549

(22) PCT Filed: Apr. 11, 2011
(86) PCT No.: PCT/CN11/72584

§ 371 Date: Jun. 17, 2011

(30) Foreign Application Priority Data
Mar. 29, 2011 (CN) 201110077477.6

(51) Int. Cl. H01L 21/316; B82Y 40/00

(52) U.S. Cl. 438/765; 977/755; 257/E21.284

(57) ABSTRACT

A semiconductor fabrication method is provided, in which a protective layer is deposited on the dummy wafer such that the protective layer fully encases the dummy wafer. Therefore, the dummy wafer will not be oxidized during thermal oxidation, thereby reducing dummy wafer consumption, decreasing production cost, avoiding particulate matter produced due to oxidation of the dummy wafer, and preventing the wafer to be oxidized from contamination.

### CROSS-REFERENCE TO RELATED APPLICATION

This application is a Section 371 national stage application of International Application No. PCT/CN2011/072584 filed on Apr. 11, 2011, which claims priority to CN201110077477.6 filed on Mar. 29, 2011, the contents of which are incorporated herein by reference in their entirety.

### FIELD OF THE INVENTION

The present invention relates to a semiconductor fabrication method, and in particular to a semiconductor fabrication method in which thermal oxidation is performed with dummy wafers.

### BACKGROUND OF THE INVENTION

Thermal oxidation is one of the most common processes in semiconductor fabrication. Normally, thermal oxidation is performed in a furnace, where dummy wafers are introduced to reduce the loading effect and to improve the uniformity by thermal oxidation. Now refer to FIG. 1, which illustrates wafers to be oxidized 12 for fabricating semiconductor devices, dummy wafers 10 and monitor wafers 11 in a thermal oxidation furnace. As the boat is not tilled up with the wafers to be oxidized 12, in order to avoid reduced oxide uniformity resulting from the loading effect, a plurality of dummy wafers 10 are introduced, so that the wafers may be oxidized equally throughout the boat and between batches. The dummy wafers 10 are normally bare wafers. As shown in FIG. 2, with thermal oxidation, a thickness A of the wafer is consumed and a silicon oxide 14 appears, causing the thermal oxidation reaction interface to move inside the dummy wafer 10. After a number of times of thermal oxidation, e.g. 20, the silicon oxide on the outer surface of the dummy wafer 10 has to be removed by hydrometallurgy. And through continuous thermal oxidations and hydrometallurgy processes, the dummy wafer 10 becomes thinner and thinner, so thin that it should be replaced with a new one. In practice, this consumes a large amount of dummy wafers, resulting in increased production cost; moreover, particulate matter may be produced by the oxidation of dummy wafers, which may have a negative effect on the wafers to be oxidized 12. Therefore, a new thermal oxidation process is desired, to reduce dummy wafer consumption, and to avoid produced particulate matter which may cause contamination.

### SUMMARY OF THE INVENTION

The present invention provides a semiconductor fabrication method using silicon nitride-coated dummy wafers, which may reduce dummy wafer consumption and avoid generation of particulate matter.

The present invention provides a semiconductor fabrication method, including:
providing a wafer to be oxidized;
providing a dummy wafer; and
arranging the wafer to be oxidized and the dummy wafer in a thermal oxidation tool, to perform thermal oxidation,
wherein the method further comprises, before performing the thermal oxidation, depositing a protective layer on an outer surface of the dummy wafer such that the protective layer fully encases the dummy wafer.

In the method according to the present invention, the thermal oxidation tool may be a thermal oxidation furnace.

In the method according to the present invention, the protective layer may be a silicon nitride film; the silicon nitride film may be formed by chemical vapor deposition (CVD), physical vapor deposition (PVD) or atomic layer deposition (ALD); preferably, the silicon nitride film is formed by Low-pressure CVD (LPCVD) at the temperature of 760° C.

In the method according to the present invention, the protective layer may have a thickness ranging from 500 Å to 1000 Å.

The present invention has the advantages that: a protective layer is deposited on the dummy wafer such that the protective layer fully encases the dummy wafer; consequently, the dummy wafer will not be oxidized during thermal oxidation, which may reduces dummy wafer consumption, decreases production cost, avoids particulate matter produced due to oxidation of the dummy wafer, and prevents the wafer to be oxidized from contamination.

### BRIEF DESCRIPTION OF THE DRAWINGS

FIG. 1 illustrates a thermal oxidation process with dummy wafers;

FIG. 2 illustrates a bare dummy wafer and how it is oxidized; and

FIG. 3 illustrates a dummy wafer encased with a protective layer.

### DETAILED DESCRIPTION OF THE INVENTION

Technical features and effects of the technical solution of the invention will be described in details hereinafter with reference to the accompanying drawings in connection with the exemplary embodiments.

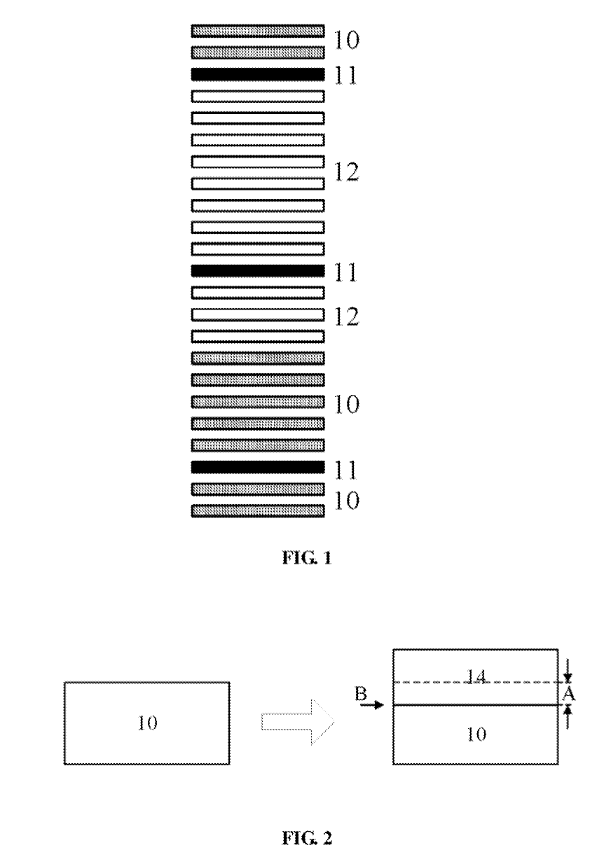

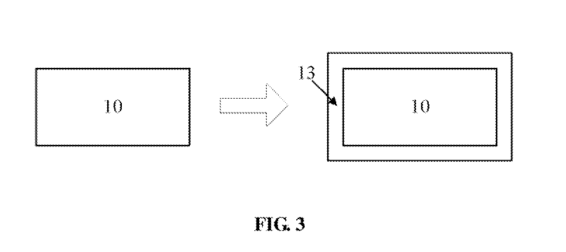

First, wafers to be oxidized 12, dummy wafers 10 and monitor wafers 11 are provided. In the case where the wafers to be oxidized 12 cannot fill up the thermal oxidation tool, a certain amount of dummy wafers 10 have to be introduced in the thermal oxidation tool, so that the wafers in whole would fill up the thermal oxidation tool, to avoid the loading effect and to have the wafers oxidized equally throughout the thermal oxidation tool and between batches. Reference can be made to FIG. 1.

Before loading the wafers into the thermal oxidation tool to perform thermal oxidation, a protective layer 13 is deposited on the outer surface of the dummy wafer 10 such that the protective layer 13 fully encases the dummy wafer 10, as shown in FIG. 3. Preferably, the protective layer 13 is a silicon nitride film. In the case where the protective layer 13 is a silicon nitride film, it may be deposited by a conventional silicon nitride film-forming process, e.g., chemical vapor deposition (CVD), physical vapor deposition (PVD) or atomic layer deposition (ALD). Preferably, the silicon nitride film is formed by Low-pressure CVD (LPCVD), a typical processing temperature being 760° C. LPCVD can realize full encasement and good denseness of the silicon nitride film, thereby providing better protection for the dummy wafer 10; moreover, the formed film is dense and no impurity particles are produced, thereby ensuring the quality of the wafer to be oxidized 12. In addition, in order to protect the dummy wafer 10 effectively, the protective layer 13 should have a certain thickness, e.g., 500-1000 Å.

Next, the wafers to be oxidized 12, the dummy wafers 10 and the monitor wafers 11 are arranged in the thermal oxidation tool, to perform thermal oxidation. The thermal oxidation tool may be a thermal oxidation furnace; and a monitor wafer 11 may be positioned in each of the upper, middle and lower sections of the furnace, for monitoring the process in the sections of the furnace.

When the thermal oxidation is over, the wafers are pulled out of the thermal oxidation tool, among which, the wafers to be oxidized 12 will go through subsequent processing processes, to form desired semiconductor devices; and the dummy wafers 10 can be used again, because they are not oxidized due to the protection by the protective layer 13.

Therefore, in the invention, a protective layer 13 is deposited on the dummy wafer 10 such that the protective layer 13 fully encases the dummy wafer. Being protected by the protective layer 13, the dummy wafer is not oxidized during thermal oxidation; consequently, the hydrometallurgy process for removing the silicon oxide in the prior art is no longer necessary. Hence, dummy wafer consumption is reduced, production cost is decreased, particulate matter produced due to oxidation of the dummy wafer 10 is avoided, and the wafer to be oxidized is prevented from contamination.

The present invention is described above in connection with the exemplary embodiments. It should be noted that a variety of alternations and equivalents may be made to the technical solution of the invention by those skilled in the art without deviation from the scope of the invention. In addition, many situation-specific and material-specific modifications can be made based on the disclosure herein. Therefore, the embodiments disclosed herein are for exemplary purpose only and should not be interpreted as limiting the scope of the invention.

1. A semiconductor fabrication method, comprising:
providing a wafer to be oxidized;
providing a dummy wafer; and
arranging the wafer to be oxidized and the dummy wafer in a thermal oxidation tool, to perform thermal oxidation,
wherein the method further comprises, before performing the thermal oxidation, depositing a protective layer on an outer surface of the dummy wafer such that the protective layer fully encases the dummy wafer.

2. The semiconductor fabrication method according to claim 1, wherein the thermal oxidation tool is a thermal oxidation furnace.

3. The semiconductor fabrication method according to claim 1, wherein the protective layer is a silicon nitride film.

4. The semiconductor fabrication method according to claim 3, wherein the silicon nitride film is formed by chemical vapor deposition (CVD), physical vapor deposition (PVD), or atomic layer deposition (ALD).

5. The semiconductor fabrication method according to claim 3, wherein the silicon nitride film is formed by Low-pressure CVD (LPCVD) at the temperature of 760° C.

6. The semiconductor fabrication method according to claim 1, wherein the protective layer has a thickness ranging from 500 Å to 1000 Å.
